(19) United States
(12) Patent Application Publication
(10) Pub. No.: US 2011/0261541 A1
(43) Pub. Date: Oct. 27, 2011

(54) DRIVING DEVICE, DISPLAY PANEL MODULE, DISPLAY APPARATUS, AND METHOD OF MANUFACTURING DRIVING DEVICE

(75) Inventors: Munehiko Ogawa, Kyoto (JP); Hiromi Kitayama, Kyoto (JP); Tomoya Ishikawa, Osaka (JP); Hiroshi Kojima, Shiga (JP); Kazuyoshi Nishi, Kyoto (JP); Tooru Suyama, Kyoto (JP)

(73) Assignee: PANASONIC CORPORATION, Osaka (JP)

(21) Appl. No.: 13/125,745

(22) PCT Filed: Oct. 13, 2010
(86) PCT No.: PCT/JP2010/006079

§ 371 Date: Apr. 22, 2011

(30) Foreign Application Priority Data
Dec. 10, 2009 (JP) 2009-280273

(51) Int. Cl. H05K 1/02; H05K 3/30

(52) U.S. Cl. 361/749; 174/254; 29/832

(57) ABSTRACT

The present invention provides a driving device, a display panel module, a display apparatus, and a method of manufacturing the driving device, which are capable of reducing the number of a driving circuit elements without reducing the number of display panels to be taken or increasing a wiring area of a film. The driving device according to an aspect of the present invention drives a display panel and includes: a film on which wires and a circuit element are mounted; and a first film portion and a second film portion separated by providing a first slit in the film. Each of the first film portion and the second film portion is folded at least once and connected to the display panel.

### TECHNICAL FIELD

The present invention relates to a driving device (display panel driving device) mounted on a display panel such as a liquid crystal panel and an organic electroluminescence panel, a display panel module using the driving device, and a display apparatus, and a method of manufacturing the driving device.

### BACKGROUND ART

In recent years, display devices mounted on display apparatuses have been shifting from devices using cathode-ray tubes to devices using liquid crystal panels (display panels) having a variety of advantages such as low power consumption and space saving.

However, the liquid crystal panels cost several times as much as cathode-ray tubes at the moment. Thus it is indispensable, for further expanding the market for the liquid crystal panels, to lower the costs for the liquid crystal panels and peripheral equipment.

The number of semiconductor devices 54 used in a display apparatus shown in FIG. 15A increases as the size of liquid crystal panels increase, which entails a significant increase in the size of a wiring board 61 connected to an input terminal of each of the semiconductor devices 54. The weight of the wiring board 61 increases as the size of the wiring board 61 increases, which may cause failure such as wire disconnection due to an excess stress applied to a connecting portion to each of the semiconductor devices 54. In addition, the size of a liquid crystal panel module (display panel module) increases due to inclusion of the wiring board 61. This is a setback against the current trend toward lightening, thinning, and shortening of the module.

Furthermore, a carrier tape (film) used as a base material in semiconductor devices such as the tape carrier package (TCP), the chip on film (COF), or the like is highly expensive, and thus a large number of circuit elements inevitably cause an increase in costs. Therefore, lowering the costs for the base material, the number of the circuit elements, and the costs for the carrier tape is indispensable if further cost reduction is desired.

Conventionally, various inventions with a variety of ingenuities provided to semiconductor devices have been proposed aiming such cost reduction.

In the first example of the conventional art, semiconductor devices are directly connected to each other for avoiding the need to mount a substrate for fixing the semiconductor devices. This is disclosed in, for example, PTL 1, and the following describes the details.

FIG. 15B shows a plan view of a liquid crystal panel module disclosed by PTL 1. FIG. 15C shows an enlarged view of two semiconductor devices 200 mounted, next to one another, on a liquid crystal panel 201 in the liquid crystal panel module.

In the liquid crystal panel module shown in FIG. 15B, plural semiconductor devices 200 are mounted on an upper and a lower outer edge of the liquid crystal panel 201 using the TCP technology. Each of the semiconductor devices 200 includes: a semiconductor chip (semiconductor element) 202 which is generally rectangular, as a driving circuit element which composes a liquid crystal driver and the like; an outer lead 203 located on an output side and an outer lead 204 located on the side of input terminal (input side). The semiconductor chip 202 is plastic molded.

In the semiconductor device 200, a slit 205 is provided on a base material on which the input-side outer lead 204 is formed as shown in FIG. 15C. Each of the semiconductor devices 200 is connected to adjacent semiconductor devices 200 one another through the outer lead 204 extending along a longitudinal side of the semiconductor elements 202 Here, each of the semiconductor devices 200 is connected to the liquid crystal panel 201 through the output-side outer lead 203 as in a conventional manner. However, the adjacent semiconductor devices 200 are connected to one another by overlapping the slit 205 with each other, so that the outer leads 204 are connected one another.

As described above, the need for mounting a wiring board for connecting the semiconductor devices one another, which is shown as the wiring board 61 in FIG. 15A, is eliminated by providing the outer lead 204 at the ends of the semiconductor element 202 in each of the semiconductor devices 200 and connecting adjacent semiconductor devices 200 using the outer leads 204, thereby allowing miniaturization of the liquid crystal panel and cost reduction.

Furthermore, in the second example of conventional art, a carrier tape on which a semiconductor element is mounted is shaped down for the purpose of cost reduction. This is described in, for example, PTL 2, and the following describes the details.

PTL 2 discloses a semiconductor device 401 including semiconductor elements on a single carrier tape having a wiring layer on an insulative film base material, as shown in FIG. 16. Each of the semiconductor elements 403 is generally rectangular and has longitudinal sides aligned along longitudinal sides of the carrier tape. The film base material is disposed between the semiconductor elements 403 adjacent to each other and the adjacent semiconductor elements 403 are connected to each other through the wiring layer formed on the film base material.

With the configuration described above, the semiconductor elements 403 are collectively mounted on the singe carrier tape, resulting in the advantageous effects described below.

Reducing the number of expensive carrier tapes allows cost reduction, and since the mounting process for connecting the semiconductor device to a display panel can be done with a single step, cost reduction by reducing the number of steps can also be achieved.

Unlike the case of mounting semiconductor devices including semiconductor elements each of which is separately packaged, it is not necessary to include a wiring board for connecting semiconductor devices one another, and thus cost reduction and miniaturization of the size of the display panel module can be achieved.

### CITATION LIST

### Patent Literature

### [PTL 1]

Japanese Unexamined Patent Application Publication No. 5-297394

### [PTL 2]

Japanese Unexamined Patent Application Publication No. 2003-330041

### SUMMARY OF INVENTION

### Technical Problem

However, with the configuration disclosed by PTL 1, for example, although the wiring board 61 shown in FIG. 15A is eliminated and a failure due to wire disconnection and an increase in the size of the liquid crystal panel module is prevented, there in no change in the usage amount of the base material (carrier tape) in the semiconductor device 200 and the base materials as many as the semiconductor elements 202 are necessary, and thus there is a problem that cost reduction cannot be achieved by reducing the number of the base materials.

In addition, with the configuration disclosed by PTL 2, there is a problem stated as below, even when the semiconductor device 401 is provided in the center area of the liquid crystal panel 400 due to the recent trend of increase in size of display panels.

(1) When dealing with the increase in size or heightening of resolution without changing the size of the carrier tape, it is necessary to enlarge a wiring area for wires 402 on the liquid crystal panel 400 to install wires for connecting the semiconductor element 403 and the liquid crystal panel 400.

There is therefore a problem that the number of liquid crystal panels 400 to be taken decreases and the costs for the liquid crystal panel 400 rises.

(2) In addition, when dealing with the increase in size or heightening of resolution without changing the area for the wires 402 on the liquid crystal panel 400, it is necessary to enlarge a wiring area of the carrier tape to install wires for connecting the semiconductor element 403 and the liquid crystal panel 400.

Thus, while cost reduction can be achieved for compact display panels, there is a problem that, when it comes to large-size panels and high-resolution panels, the advantageous effect of cost reduction cannot be obtained because the costs rise due to the need to increase the usage amount of the carrier tape because of the rise in the number of wires for control signals which are transmitted from the semiconductor elements and drive the display panel.

The present invention has been conceived in view of the above-described problems, and it is an object thereof to provide a driving device, a display panel module, a display apparatus, and a method of manufacturing the driving device, which are capable of reducing the number of a driving circuit element without reducing the number of display panels to be taken or increasing a wiring area of a film.

### Solution to Problem

A driving device according to an aspect of the present invention is a driving device for driving a display panel, the driving device comprising: wires; a circuit element; a film on which the wires and the circuit element are mounted; and a first film portion and a second film portion separated by providing a first slit in the film, wherein each of the first film portion and the second film portion is folded at least once and connected to the display panel.

With this configuration, it is possible to use a more area for wiring, on a film, for wires connecting the circuit element and substrate wires on the display panel. As a result, since the driving device can be implemented which is capable of reducing the number of driving circuit elements without reducing the number of display panels to be taken or increasing the wiring area of a film even when used for a large-size display panel, it is possible to obtain an advantageous effect of lowering costs.

Furthermore, in the driving device according to an aspect of the present invention, the first slit may be linear.

With this configuration, since a film portion can be separated into two or more portions at a slit without a bend, an advantageous effect is obtained which enables implementation of the driving device that can be used also for a large-size display panel with only a small number of steps added.

Furthermore, in the driving device according to an aspect of the present invention, each of the first film portion and the second film portion may further be provided with a second slit having a bend.

With this configuration, since the slit having a bend is provided, each of the first film portion and the second film portion can be folded using a bent slit and wires of the film to be connected to the substrate wires of the display panel can be elongated, and thus an advantageous effect is obtained which enables implementation of a driving device that can be used for a larger-size display panel.

Furthermore, the driving device according to an aspect of the present invention may further comprise a crack prevention part at an end of at least one of the first slit and the second slit in the film.

With this configuration, it is possible, in the display panel module configured by mounting the driving device onto the display panel, to prevent a slit provided on the film from producing a further crack due to vibration or horizontal oscillation applied to the display panel, and thus an advantageous effect is produced which prevents a crack on the film and disconnection of wires due to the crack.

Furthermore, in the driving device according to an aspect of the present invention, each of the first film portion and the second film portion may be folded an even number of times and connected to the display panel.

With this configuration, it is possible to change the shape of the driving device without vertically inverting the circuit element and the wires on the film, and thus to obtain an advantageous effect which enables implementation of the driving device that can be used for a large-size display panel.

Furthermore, in the driving device according to an aspect of the present invention, each of the first film portion and the second film portion may be folded an odd number of times and connected to the display panel.

This configuration allows the driving device to have a configuration in which the circuit element and the wires on the film vertically invert.

Furthermore, in the driving device according to an aspect of the present invention, a width of each of said wires may be enlarged at a folding position of said film.

With this configuration, it is possible to obtain an advantageous effect of reducing the rate of disconnection of wires at a folding position on the film.

Furthermore, in the driving device according to an aspect of the present invention, the wires may be not provided at folding positions where the film is folded more than once

With this configuration, it is possible to obtain an advantageous effect of reducing the rate of disconnection of wires of the driving device.

Furthermore, in the driving device according to an aspect of the present invention, each of the first film portion and the second film portion may be folded along a line which serves as a folding position, the line being at a 45 degrees angle with respect to the first slit.

With this configuration, in the driving device in which each of the first film portion and the second film portion is folded in right and left to be the shape as mounted, the distance between the left end to the right end of the folded first film portion and the second film portion can be maximized, and thus it is possible to implement a driving device that can be used for a large-size display panel with a small amount of film materials and to obtain an advantageous effect of cost reduction.

Furthermore, in the driving device according to an aspect of the present invention, each of the first film portion and the second film portion may be folded along a line which serves as a folding position, the line being at a less than 45 degrees angle with respect to the first slit.

With this configuration, it is possible to produce, in the driving device in which each of the first film portion and the second film portion is folded in right and left to be the shape as mounted, an area in which the same portion can be folded twice or more. Therefore, a process for reducing the rate of disconnection of wires is not necessary even when the same portion needs to be folded twice ore more, and thus it is possible to implement the driving device with a minimum wiring area. In other words, the usage amount of the film can be minimized, and thus it is possible to obtain an advantageous effect of cost reduction.

Furthermore, in the driving device according to an aspect of the present invention, each of the first film portion and the second film portion may be folded with a constant curvature.

With this configuration, in a display panel module including a display panel on which the driving device is mounted, the curvature that has been kept constant changes when vibration or horizontal oscillation is applied to the display panel. As a result, vibration and shock are absorbed. This allows obtaining the advantageous effect of reducing the rate of disconnection of the wires positioned at folding positions of the driving device, and reducing the rate of disconnection of the wires connecting the driving device and the substrate wires on the display panel.

Furthermore, the driving device according to an aspect of the present may further comprise a curvature fixing unit configured to maintain the constant curvature.

With this configuration, in a display panel module including a display panel on which the driving device is mounted, the curvature that has been kept constant can change when vibration or horizontal oscillation is applied to the display panel, or the curvature can return to a constant curvature using the curvature fixing unit after the curvature changed. Therefore, it is possible to keep the curvature constant even after vibration or shock is applied.

More specifically, it is possible to obtain the advantageous effect of reducing the rate of disconnection of the wires positioned at folding positions of the driving device, and reducing the rate of disconnection of the wires connecting the driving device and the substrate wires on the display panel.

Furthermore, in the driving device according to an aspect of the present invention, a folded portion and a non-folded portion in the film may be bonded to each other using an adhesive material.

Since the shape of the driving device is fixed with this configuration, the shape of the wires positioned at the folding positions is less likely to change when vibration or horizontal oscillation is applied to the display panel, in a display panel module including a display panel on which the driving device is mounted, it is possible to obtain an advantageous effect of reducing the rate of disconnection of the wires of the driving device.

Furthermore, in the driving device according to an aspect of the present invention, the first film portion may include a third film portion and a fourth film portion separated by providing a third slit in the first film portion, the second film portion may include a fifth film portion and a sixth film portion separated by providing a fourth slit in the second film portion, the third film portion may be folded and inserted into the third slit, and the fifth film portion may be folded and inserted into the fourth slit.

Since the shape of the driving device is fixed with this configuration, the shape of the wires positioned at the folding positions is less likely to change when vibration or horizontal oscillation is applied to the display panel, in a display panel module including a display panel on which the driving device is mounted, it is possible to obtain an advantageous effect of reducing the rate of disconnection of the wires of the driving device.

Furthermore, the driving device according to an aspect of the present invention may further comprise a bend preventing material in the fourth film portion and the sixth film portion, the bend preventing material being more resistant to bending than the fourth film portion and the sixth film portion.

Since the shape of the driving device is further fixed with this configuration, the shape of the wires positioned at the folding positions is less likely to change when vibration or horizontal oscillation is applied to the display panel, in a display panel module including a display panel on which the driving device is mounted, it is possible to obtain an advantageous effect of reducing the rate of disconnection of the wires of the driving device.

Furthermore, in the driving device according to an aspect of the present invention, the third film portion may be provided with a cut into which the fourth film portion is inserted, and the fifth film portion may be provided with a cut into which the sixth film portion is inserted.

Since the shape of the driving device is further fixed with this configuration, the shape of the wires positioned at the folding positions is less likely to change when vibration or horizontal oscillation is applied to the display panel, in a display panel module including a display panel on which the driving device is mounted, it is possible to obtain an advantageous effect of reducing the rate of disconnection of the wires of the driving device.

In addition, a display panel module according to an aspect of the present invention includes a display panel and the driving device described above mounted on an outer edge of the display panel.

With this configuration, it is possible to obtain a display panel module having the advantageous effects described above for the aforementioned driving device.

In addition, a display apparatus according to an aspect of the present invention comprises: a display panel; the driving device descried above; and a fixing frame for fixing a position of the display panel and the driving device, the display panel and the driving device being provided inside the fixing frame.

With this configuration, it is possible to obtain a display apparatus such as a television or monitor having the advantageous effects described above for the aforementioned driving device, and particularly a display apparatus having a high heat dissipation effect.

Furthermore, in the display apparatus according to an aspect of the present invention, the circuit element may directly be in contact with the fixing frame.

This configuration allows crimping the circuit element directly to the fixing frame when mounting the driving device onto the display apparatus such as a television or a monitor, and thus a high heat dissipation effect can be obtained.

Furthermore, in the display apparatus according to an aspect of the present invention, the circuit element may be in contact with the fixing frame via a material having high thermal conductivity.

This configuration allows sandwiching a material with high thermal conductivity between the circuit element and the fixing frame, and thus a higher heat dissipation effect can be obtained.

In addition, a method of manufacturing a driving device according to an aspect of the present invention is a method of manufacturing a driving device which drives a display panel and includes wires, a circuit element, and a film on which the wires and the circuit element are mounted, the method comprises providing a first slit in the film to separate part of the film into a first film portion and a second film portion, and folding each of the first film portion and the second film portion at least once to connect the first film portion and the second film portion to the display panel.

With this configuration, it is possible to obtain a method of manufacturing a driving device having the advantageous effects described above for the aforementioned driving device.

### Advantageous Effects of Invention

A driving device, a display panel module, a display apparatus, and a method of manufacturing the driving device according to an aspect of the present invention allow use of a more area for wiring of wires connecting a circuit element and substrate wires, by folding each of the first film portion and the second film portion separated by providing a slit in a film of the driving device to be connected to substrate wires of a display panel. As a result, it is possible to implement a driving device, display panel module, a display apparatus, and a method of manufacturing the driving device which are capable of reducing the number of driving circuit elements without reducing the number of display panels to be taken or increasing the wiring area of a film even when used for a large-size display panel, and thus an advantageous effect of lowering costs can be obtained. Furthermore, an advantageous effect of lowering heat can also be obtained.

### BRIEF DESCRIPTION OF DRAWINGS

FIG. 1A is a plan view which shows a configuration of a display panel module according to Embodiment 1 of the present invention.

FIG. 1B is a plan view which shows a shape of a driving device before mounted on a liquid crystal panel, according to Embodiment 1.

FIG. 2A is an enlarged plan view of a portion of the driving device, according to Embodiment 1.

FIG. 2B is an enlarged plan view of a portion of the driving device, according to Embodiment 1.

FIG. 3A is a plan view which shows a shape of the driving device before mounted on the liquid crystal panel, according to Embodiment 1.

FIG. 3B is a plan view which shows a shape of the driving device mounted on the liquid crystal panel, according to Embodiment 1.

FIG. 4A is a cross-sectional view of a display apparatus according to Embodiment 1.

FIG. 4B is a cross-sectional view of the display apparatus according to Embodiment 1.

FIG. 4C is a cross-sectional view of the display apparatus according to Embodiment 1.

FIG. 5A is a plan view which shows a shape of a driving device before mounted on the liquid crystal panel, according to Modification 1 of Embodiment 1.

FIG. 5B is an enlarged plan view of a portion of the driving device, according to Modification 1 of Embodiment 1.

FIG. 6A is a plan view which shows a shape of the driving device before mounted on the liquid crystal panel, according to Modification 1 of Embodiment 1.

FIG. 6B is a plan view which shows a shape of the driving device mounted on the liquid crystal panel, according to Modification 1 of Embodiment 1.

FIG. 6C is an enlarged plan view of a portion of the driving device, according to Modification 1 of Embodiment 1.

FIG. 7A is a plan view which shows a configuration of a display panel module according to Embodiment 2 of the present invention.

FIG. 7B is a plan view which shows a shape of a driving device before mounted on a liquid crystal panel, according to Embodiment 2.

FIG. 7C is a plan view which shows a shape of the driving device mounted on the liquid crystal panel, according to Embodiment 2.

FIG. 8A is a plan view which shows a shape of the driving device before mounted on the liquid crystal panel, according to Modification 2 of Embodiment 2.

FIG. 8B is a plan view which shows a shape of the driving device mounted on the liquid crystal panel, according to Modification 2 of Embodiment 2.

FIG. 8C is an enlarged plan view of a portion of the driving device, according to Modification 2 of Embodiment 2.

FIG. 9A is a plan view which shows a configuration of a display panel module according to Embodiment 3 of the present invention.

FIG. 9B is a plan view which shows a shape of a driving device before mounted on the liquid crystal panel, according to Embodiment 3.

FIG. 9C is a plan view which shows a shape of the driving device mounted on the liquid crystal panel, according to Embodiment 3.

(a) in FIG. 10A is a plan view which shows a configuration of a display panel module according to Embodiment 4 of the present invention. (b) in FIG. 10A is a side view which shows a shape of the driving device mounted on the liquid crystal panel, according to Embodiment 4.

(a) in FIG. 10B is a plan view which shows a configuration of a display panel module according to Embodiment 5 of the present invention. (b) in FIG. 10B is a side view which shows a shape of the driving device mounted on the liquid crystal panel, according to Embodiment 5.

FIG. 11A is a plan view which shows a shape of a driving device before mounted on a liquid crystal panel, according to Embodiment 6 of the present invention.

FIG. 11B is a plan view which shows a shape of the driving device before mounted on the liquid crystal panel, according to Embodiment 6.

FIG. 11C is a plan view which shows a shape of the driving device mounted on the liquid crystal panel, according to Embodiment 6.

FIG. 12A is a plan view which shows a shape of the driving device before mounted on the liquid crystal panel, according to Embodiment 6.

FIG. 12B is a plan view which shows a shape of the driving device before mounted on the liquid crystal panel, according to Embodiment 6.

FIG. 12C is a plan view which shows a shape of the driving device mounted on the liquid crystal panel, according to Embodiment 6.

FIG. 13A is a plan view which shows a shape of the driving device before mounted on the liquid crystal panel, according to Embodiment 6.

FIG. 13B is a plan view which shows a shape of the driving device before mounted on the liquid crystal panel, according to Embodiment 6.

FIG. 13C is a plan view which shows a shape of the driving device mounted on the liquid crystal panel, according to Embodiment 6.

FIG. 14 is a plan view which shows a shape of a driving device before mounted on a liquid crystal panel, according to a modification of the embodiments of the present invention.

FIG. 15A is a plan view which shows a configuration of a general display apparatus.

FIG. 15B is a plan view of a liquid crystal panel module according to PTL 1.

FIG. 15C is an enlarged plan view of a portion of a liquid crystal panel module according to PTL 1.

FIG. 16 is a plan view of a liquid crystal panel module according to PTL 2.

### DESCRIPTION OF EMBODIMENTS

The following describes the best mode for carrying out the present invention, with reference to the drawings. It is to be noted that components which share the same reference numeral perform the same operation, and thus explanation is not repeated in some cases.

### Embodiment 1

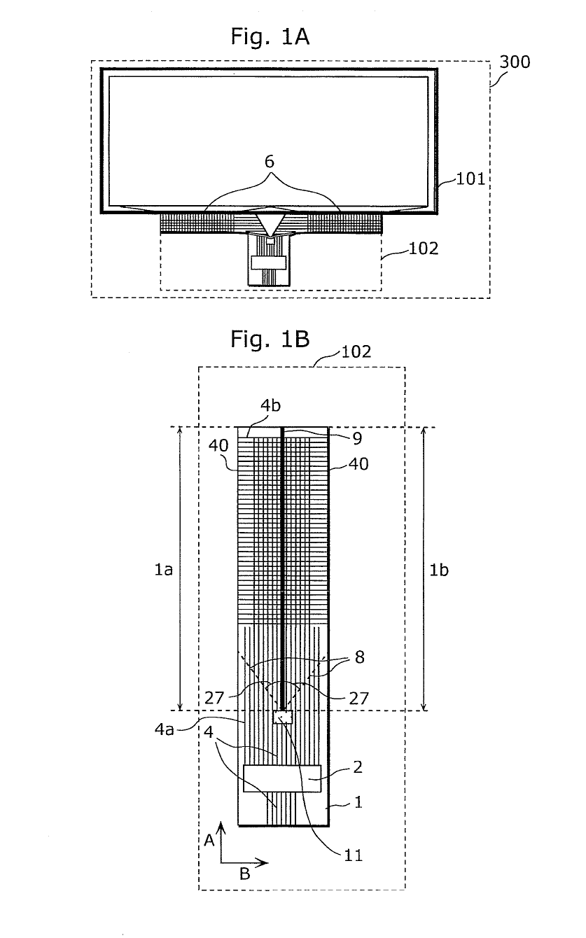

FIG. 1A is a plan view which shows a configuration of a display panel module 300 according to this embodiment. FIG. 1B is a plan view which shows a shape of a driving device 102 before mounted on a liquid crystal panel 101, according to this embodiment. In FIG. 1A, the display panel module 300 includes: the liquid crystal panel 101; and the driving device 102 which is connected to substrate wires 6 included in the liquid crystal panel 101 and drives the liquid crystal panel 101. The driving device 102 is mounted on an outer edge of the liquid crystal panel 101 and includes a film 1 on which wires 4 and a circuit element 2 are mounted.

It is to be noted that, the display panel is described here as a liquid crystal panel; however, the same effect can be obtained with a thin display such as an organic electroluminescence panel or a plasma display.

As shown in FIG. 1B, the driving device 102 uses the film 1 as a base material. The circuit element 2 is mounted on the film 1, and the wires 4 are provided in two layers, on one surface of the film 1, for guiding signals inputted to and outputted from the circuit element 2. The driving device 102 is a semiconductor integrated circuit element for a display circuit on which the driving circuit of the liquid crystal panel 101 is mounted, a controller circuit that controls the driving circuit of the liquid crystal panel 101, a power supply circuit for generating power, and so on.

The film 1 is provided with a linear slit 9 (a first slit) having no bend. A crack prevention part 11 is provided at the end of the slit so that a crack (a crack originated from the slit 9) due to vibration or horizontal oscillation is prevented from occurring in the film 1. The driving device 102 includes a first film portion 1a and a second film portion 1b which are obtained by separating the film 1 at the slit 9. Each of the first film portion 1a and the second film portion 1b is folded at least once to be connected to the liquid crystal panel 101. Each of the first film portion 1a and the second film portion 1b is folded, for example, an odd number of times to be connected to the liquid crystal panel 101.

The wires 4 are connected to the circuit element 2 and include: first wires 4a; and second wires 4b connected to the first wires 4a. In the state before the film 1 is folded, the first wires 4a extend in a first direction A, and the second wires 4b extend in a second direction B. The slit 9 extends in the first direction A in the state before the film 1 is folded. The film 1 has a length longer in the first direction A than a length in the second direction B in the state before the film 1 is folded. In this case, since the film 1 has a rectangular planar shape in the state before the film 1 is folded, the first direction A is the direction of the long side of the film 1 and the second direction B is the direction of the short side of the film 1, and thus the slit 9 is provided at the short side of the film 1. Terminals (electrodes) 40 connected to the second wires 4b and to be connected to the substrate wires 6, in the state before the film 1 is folded, are aligned on the long sides of the film 1 in the direction of the long side.

In manufacturing the driving device 102, part of the film 1 is separated into the first film portion 1a and the second film portion 1b by providing the film 1 with the slit 9. Each of the first film portion 1a and the second film portion 1b is folded at least once and connected to the liquid crystal panel 101, thereby being mounted on the liquid crystal panel 101.

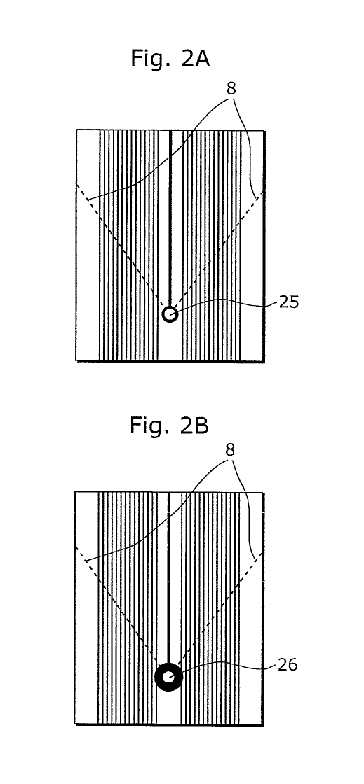

The crack prevention part 11 may be a circular hole 25 for preventing a crack, as shown in FIG. 2A, an eyelet 26 for preventing a crack provided on the film 1, as shown in FIG. 2B, or simply, a tape material bonded to the film 1, for example.

It is to be noted that the crack prevention part 11 may be omitted when a film material which is resistant to cracking is used or it can be determined that an implementation problem involving a crack is unlikely to occur even when the crack prevention part 11 is not added.

The film 1 is folded at folding positions 8, and an angle 27 between a folding line of each of the folding positions 8 and the slit 9 is, for example, 45 degrees. In other words, each of the first film portion 1a and the second film portion 1b is folded along a line which serves as a corresponding one of the folding positions 8. The line is at an angle of 45 degrees with respect to the first slit 9.

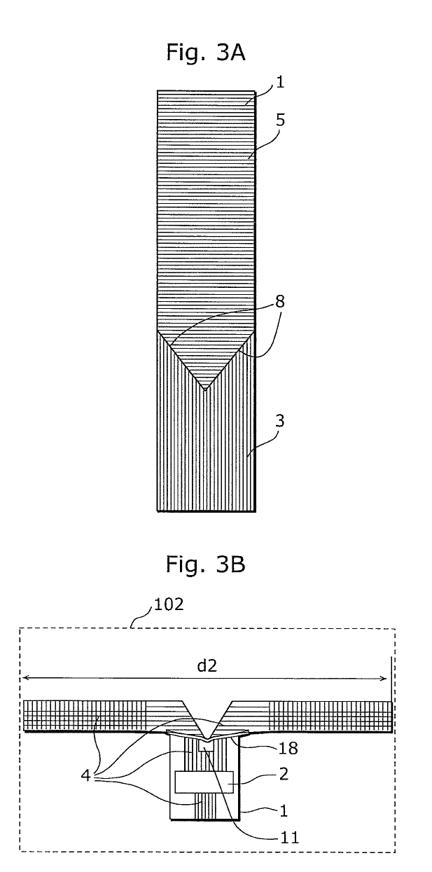

It is to be noted that, in the description below, the film 1 is separated into two portions at the folding positions 8 as shown in FIG. 3A, and the upper portion of the film 1 is called a film portion 5 and the lower portion of the film 1 is called a film portion 3. The direction of the wires 4 is different between in the film portion 5 and in the film portion 3, making an L-shape wiring on the film 1. Since edges of the wires 4 are positioned at a side of the film portion 5, it is possible to connect the edges of the wires 4 of the film portion 5 to the substrate wires 6 of the liquid crystal panel 101, by only folding the film 1 using the slit 9.

FIG. 3B is a plan view which shows a shape of the driving device 102 shown in FIG. 1B mounted on the liquid crystal panel 101.

It is possible to maximize a distance d between the left end to the right end of the film portion 5 shown in FIG. 3B, by folding the film 1 at each of the folding positions 8 where the angle 27 is 45 degrees with respect to the slit 9. With this, it is possible to implement the driving device 102 adaptable to the large-size liquid crystal panel 101 without reducing the number of the liquid crystal panel 101 to be taken with a small amount of the film material, allowing obtaining the advantageous effect of cost reduction.

When mounting the driving device 102 onto the liquid crystal panel 101, the two portions separated at the slit 9 of the film 1 are respectively folded at the folding positions 8. At this time, in order to prevent the folded film 1 from changing its shape, due to resilience, from the shape shown in the driving device 102 of FIG. 3B to the shape before mounted, the film portion 3 and the film portion 5 are bonded at an overlapping portion using an adhesive material 18 to fix the shape of the driving device 102. More specifically, the shape of the driving device 102 is fixed by bonding the folded portion (film portion 5) and the non-folded portion (film portion 3) of the film 1, using the adhesive material 18.

Since the shape of the driving device 102 is fixed by bonding the portions using the adhesive material 18, the shape of the wires 4 at the folding positions 8 is less likely to change when vibration or horizontal oscillation is applied to the liquid crystal panel 101, and thus it is possible to obtain the advantageous effect of lowering the probability of occurrence of wire disconnection of the wires 4 in the driving device 102.

In addition, given that the film 1 has a front surface where the circuit element 2 is mounted and a rear surface on the other side, the wires 4 on the film 1 face the side of the rear surface by folding an odd number of times (once, in this case) the right and left portions of the film 1 separated at the slit 9.

The wires 4 facing the side of the rear surface and the substrate wires 6 on the liquid crystal panel 101 are connected, thereby configuring the display panel module 300 shown in FIG. 1A.

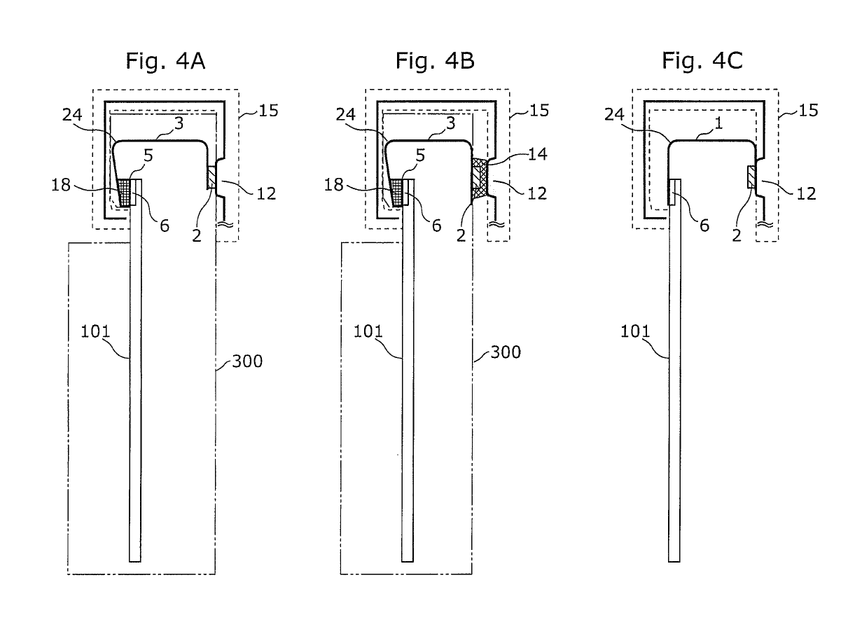

Furthermore, FIG. 4A and FIG. 4B show cross-sectional views of an example of the display apparatus including the display panel module 300 and a fixing frame 15 for a television, a monitor, and the like, according to this embodiment. FIG. 4C shows a cross-sectional view of a liquid crystal panel according to a comparison example. The liquid crystal panel 101 and the driving device 102 are provided inside the fixing frame 15 so that the positions of the liquid crystal panel 101 and the driving device 102 are fixed.

It is possible to locate the circuit element 2 on the side of the fixing frame 15 and the wires 4 of the film 1 on the side of the liquid crystal panel 101 with respect to the film 1, by folding, an odd number of times (once, in this case) each of the right and left films of the film 1 separated at the slit 9, and thus the circuit element 2 can be directly crimped to a heat dissipation unit 12 of the fixing frame 15. The fixing frame 15 includes the heat dissipation unit 12 that is a projection that projects inwardly. The circuit element 2 is directly in contact with the heat dissipation unit 12.

At this time, a folding position 24 of the film 1 to be provided in the fixing frame 15 is set so as to be on the film portion 3 so that there is no occurrence of a twice-folded position (a portion folded twice) in the same portion in the film 1.

It is to be noted that, as shown in FIG. 4B, it is possible to obtain further heat dissipation effect by including, between the heat dissipation unit 12 and the circuit element 2, a heat-conducting material 14 with high thermal conductivity such as silicon resin capable of further increasing heat dissipation effect. The fixing frame 15 includes the heat dissipation unit 12 that is a projection that projects inwardly. The circuit element 2 is in contact with the heat dissipation unit 12, in other words, with the fixing frame 15, via the heat-conducting material 14.

The circuit element 2 is directly crimped or bonded to the heat dissipation unit 12, so that the advantageous effect of heat dissipation increases compared to the configuration shown in FIG. 4C which includes the film 1 between the heat dissipation unit 12 and the circuit element 2. This solves the problem that the number of driving elements which are contained in the circuit element 2 and drive the liquid crystal panel cannot be increased, due to the upper limit of heat generation, because it is one of the factors for heat generation, allowing higher output of the circuit element 2. As a result, it is possible to configure the display panel module 300 with a fewer number of the circuit elements 2 than it used to be required, allowing further lowering the costs and module price.

### Modification Example 1

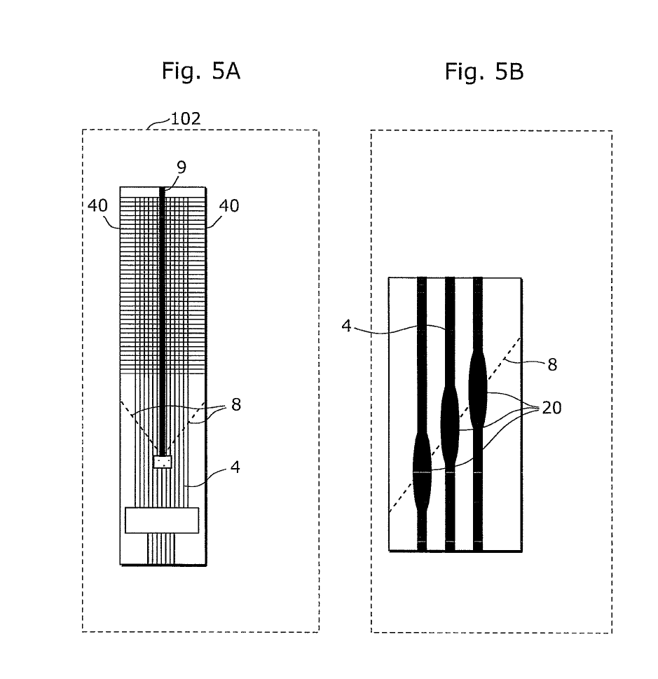

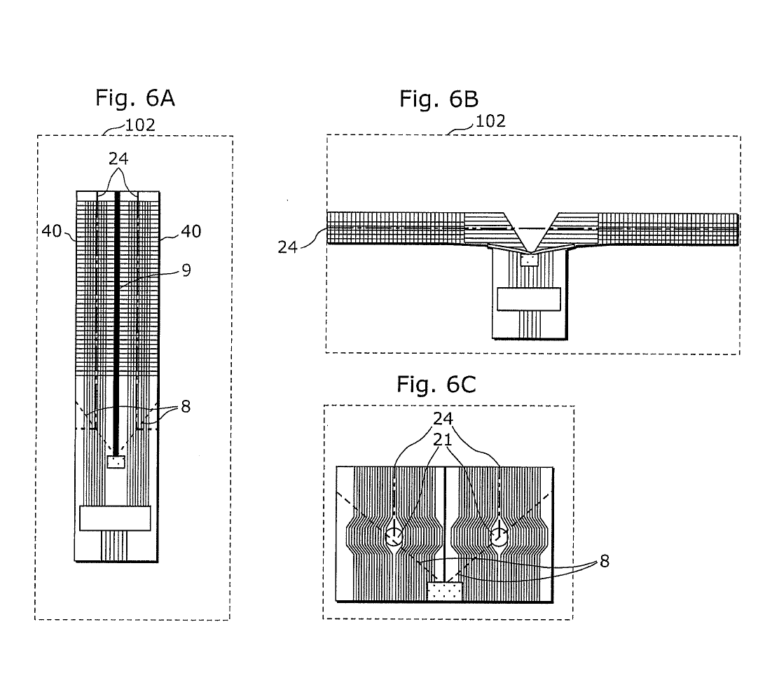

The following describes, with reference to FIG. 5A to FIG. 6C, a modification example related to addressing wire disconnection of the wires 4 on the film 1 in the driving device 102 according to the present embodiment.

FIG. 5A is a plan view which shows a shape of the driving device 102 before mounted on the liquid crystal panel 101. FIG. 5B is an enlarged view of one of the folding positions 8 and the periphery thereof of the driving device 102.

As shown in FIG. 5B, wire strengthening portions 20 having a width different from a width of the wires 4 are provided at the intersections of the wires 4 and the folding positions 8. More specifically, the line width of the wires 4 at and around the folding position of the film 1 is enlarged. This allows obtaining the advantageous effect of reducing the rate of disconnection of the wires 4 in the driving device 102.

FIG. 6A is a plan view which shows a shape of the driving device 102 before mounted on the liquid crystal panel 101. FIG. 6B is a plan view which shows a shape of the driving device 102 mounted on the liquid crystal panel 101. FIG. 6C is an enlarged view of the folding positions 8 and the periphery thereof of the driving device 102.

When the film portion 5 includes, in addition to the folding positions 8, folding positions 24 which partially overlaps the folding positions 8, a twice-folded position in the same portion appears at the intersection of the folding positions 8 and the folding positions 24. In view of the above, wiring prohibited portions 21 are provided, at the intersections of the folding positions 8 and the folding positions 24, as areas where the wires 4 are not allowed to exist. That means, the wires 4 are not provided at the folding position where the film 1 is folded more than once.

When the wires 4 are provided at the wiring prohibited portion 21, there is a possibility of disconnection of wires 4 on the film 1. As shown in FIG. 6C, it is possible to obtain the advantageous effect of reducing the rate of disconnection of the wires 4 in the driving device 102, by providing the wires 4 on the film 1 so as to avoid the wiring prohibited portions 21.

It is apparent that FIG. 6C is one of many examples of a wiring manner of the wires 4, and likewise, FIG. 5B is one of many examples of the shape of the wire strengthening portions 20.

### Embodiment 2

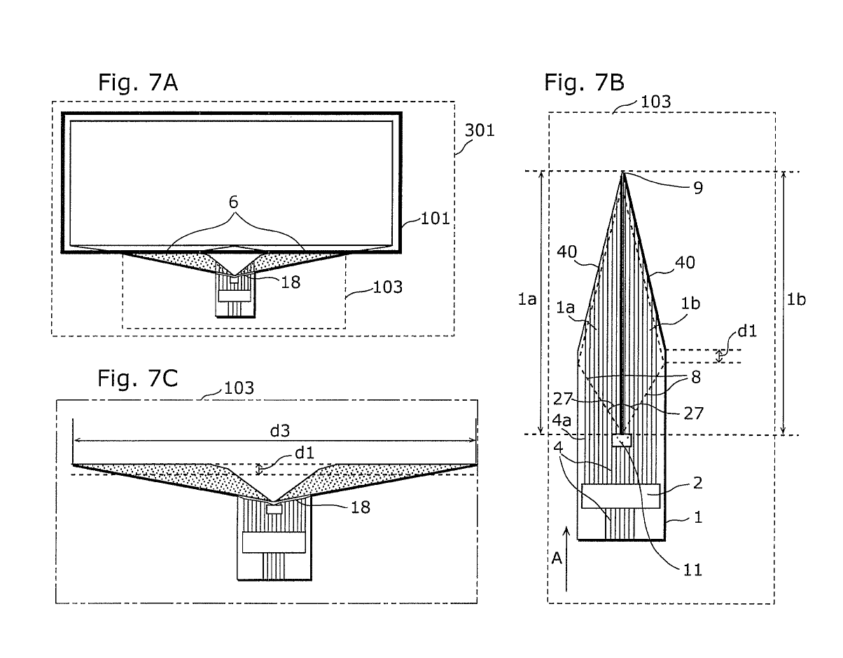

FIG. 7A is a plan view which shows a configuration of a display panel module 301 according to this embodiment. FIG. 7B is a plan view which shows a shape of a driving device 103 before mounted on a liquid crystal panel 101, according to this embodiment.

In FIG. 7A, the display panel module 301 includes: the liquid crystal panel 101; and the driving device 103 which is connected to a substrate wires 6 included in the liquid crystal panel 101 and drives the liquid crystal panel 101. The driving device 103 is mounted on an outer edge of the liquid crystal panel 101 and includes a film 1 on which wires 4 and a circuit element 2 are mounted. It is to be noted that the display panel module 301 according to this embodiment is included in a display apparatus in the same manner as in FIG. 4A to FIG. 4C.

As shown in FIG. 7B, the driving device 103 uses the film 1 as a base material. The circuit element 2 is mounted on the film 1, and the wires 4 are provided on the film 1, for guiding signals inputted to and outputted from the circuit element 2. The direction of the wires 4 is not different between in the film portion 5 and in the film portion 3, and thus the wires 4 are arranged linearly on the film 1. However, the planar shape of the film portion 5 is triangle, so that the edge of each of the wires 4 is located at an oblique side of the film portion 5. Accordingly, it is possible to connect the edges of the wires 4 of the film portion 5 to the substrate wires 6 of the liquid crystal panel 101, by only folding the film 1 using the slit 9.

The film 1 is provided with a linear slit 9 having no bend. A crack prevention part 11 is provided at the end of the slit so that a crack is prevented from occurring in the film 1 due to vibration or horizontal oscillation. The driving device 103 includes a first film portion 1a and a second film portion 1b which are obtained by separating the film 1 at the slit 9. Each of the first film portion 1a and the second film portion 1b is folded at least once to be connected to the liquid crystal panel 101. Each of the first film portion 1a and the second film portion 1b is folded, for example, an odd number of times to be connected to the liquid crystal panel 101.

The wires 4 are connected to the circuit element 2 and include first wires 4a extending in the first direction A in the state before the film 1 is folded. The slit 9 extends in the first direction A in the state before the film 1 is folded. The film 1 has a planar shape whose width gradually decreases toward the edge in the first direction A in the state before the film 1 is folded. The slit 9 is formed at the edge of the film 1 in the first direction A. At this time, the first wires 4a extend to the edge of the film 1. Terminals 40 connected to the first wires 4a and to be connected to the substrate wires 6 are provided at the edge of the film 1 in the first direction A.

In manufacturing the driving device 103, part of the film 1 is separated into the first film portion 1a and the second film portion 1b by providing the film 1 with the slit 9. Each of the first film portion 1a and the second film portion 1b is folded at least once and connected to the liquid crystal panel 101, thereby being mounted on the liquid crystal panel 101.

The crack prevention part 11 may be a circular hole 25 for preventing a crack, as shown in FIG. 2A, an eyelet 26 provided on the film 1 for preventing a crack, as shown in FIG. 2B, or simply, a tape material bonded to the film 1, for example.

It is to be noted that the crack prevention part 11 may be omitted when a film material which is resistant to cracking is used or it can be determined that an implementation problem involving a crack is unlikely to occur even when the crack prevention part 11 is not added.

The film 1 is folded at the folding positions 8, and an angle 27 between a folding line of each of the folding positions 8 and the slit 9 is, for example, less than 45 degrees. In other words, each of the first film portion 1a and the second film portion 1b is folded along a line which serves as a corresponding one of the folding positions 8. The line is at an angle of less than 45 degrees with respect to the first slit 9.

It is to be noted that an area of the film portion 5 is eliminated, which becomes unnecessary when mounted onto the display panel module as a result of folding the film 1 by less than 45 degrees.

FIG. 7C is a diagram which shows a shape of the driving device 103 shown in FIG. 7B as mounted on the liquid crystal panel 101.

Since the driving device 103 includes an area d1 as shown in FIG. 7B and FIG. 7C, which does not include a folding area, by setting the angle 27 to be less than 45 degrees, the area d1 can be folded even when there is a restriction in folding the wires 4 on the film 1 to prohibit folding the same portion twice in order to avoid disconnection of the wires 4. More specifically, since it is possible, in the area d1, to mount the driving device 103 by folding the film 1 without a measure for addressing wire disconnection, the wiring are of the wires 4 on the film 1 can be minimized. Accordingly, it is possible to minimize the usage amount of the film 1, and thus the advantageous effect of cost reduction is obtained.

In addition, the area d1 can easily be expanded by decreasing the folding angle 27 at each of the folding positions 8.

When mounting the driving device 103 onto the liquid crystal panel 101, the two portions separated at the slit 9 of the film 1 are respectively folded at the folding positions 8. At this time, in order to prevent the folded film 1 from changing its shape, due to resilience, from the shape shown in the driving device 103 of FIG. 7C to the shape before mounted, the film portion 3 and the film portion 5 are bonded at an overlapping portion using an adhesive material 18 to fix the shape of the driving device 103. More specifically, the shape of the driving device 103 is fixed by bonding the folded portion (film portion 5) and the non-folded portion (film portion 3) of the film 1, using the adhesive material 18.

In addition, given that the film 1 has a front surface where the circuit element 2 is mounted and a rear surface on the other side, the wires 4 on the film portion 5 face the side of the rear surface by folding an odd number of times (once, in this case) the right and left portions of the film 1 separated at the slit 9.

The wires 4 facing the side of the rear surface and the substrate wires 6 on the liquid crystal panel 101 are connected, thereby configuring the display panel module 301 shown in FIG. 7A.

It is possible to obtain the advantageous effect described in Embodiment 1, that is, the effect obtained by adhesive material 18, such as the effect of heat dissipation.

### Modification Example 2

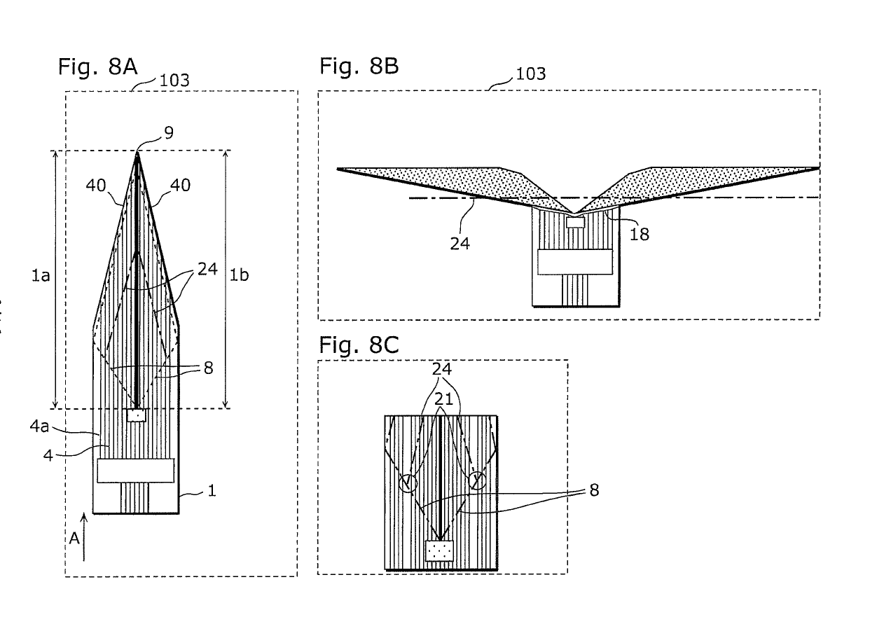

The following describes, with reference to FIG. 8A to FIG. 8C, a modification example related to a measure for addressing disconnection of the wires 4 on the film 1 in the driving device 103 according to the present embodiment.

FIG. 8A is a plan view which shows a shape of the driving device 103 before mounted on the liquid crystal panel 101. FIG. 8B is a plan view which shows a shape of the driving device 103 mounted on the liquid crystal panel 101. FIG. 8C is an enlarged view of the folding positions 8 and the periphery thereof of the driving device 103.

When the film portion 5 includes, in addition to the folding positions 8, folding positions 24 which partially overlap the folding positions 8, a twice-folded positions in the same portions appear at the intersections of the folding positions 8 and the folding positions 24. In view of the above, a wiring prohibited portions 21 are provided as areas where the wires 4 are not allowed to exist, at the intersections of the folding positions 8 and the folding positions 24.

When the wires 4 are provided at the wiring prohibited portions 21, there is a possibility of disconnection of wires 4 on the film 1. As shown in FIG. 8C, it is possible to obtain the advantageous effect of reducing the rate of disconnection of the wires 4 in the driving device 103, by providing the wires 4 on the film 1 so as to avoid the wiring prohibited portions 21.

It is apparent that FIG. 8C is one of many examples of a wiring manner of the wires 4.

### Embodiment 3

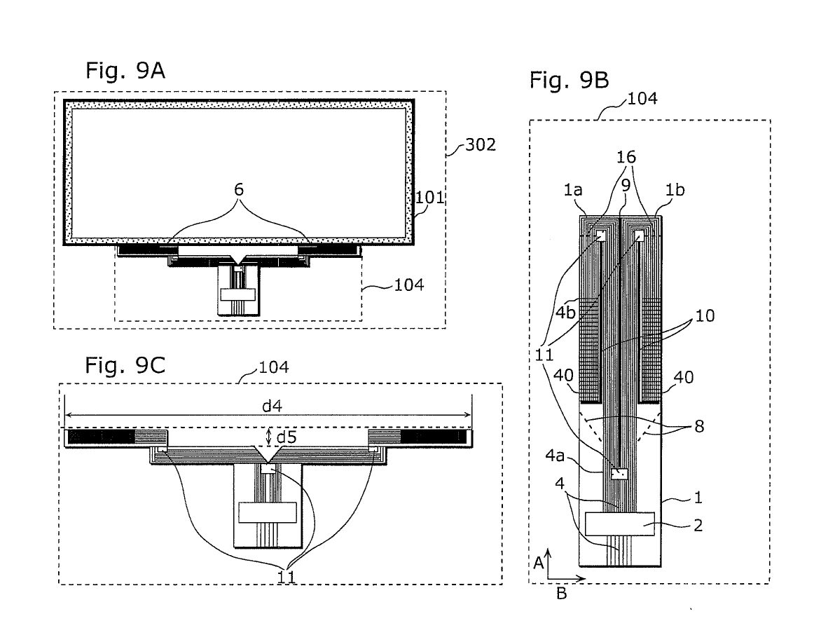

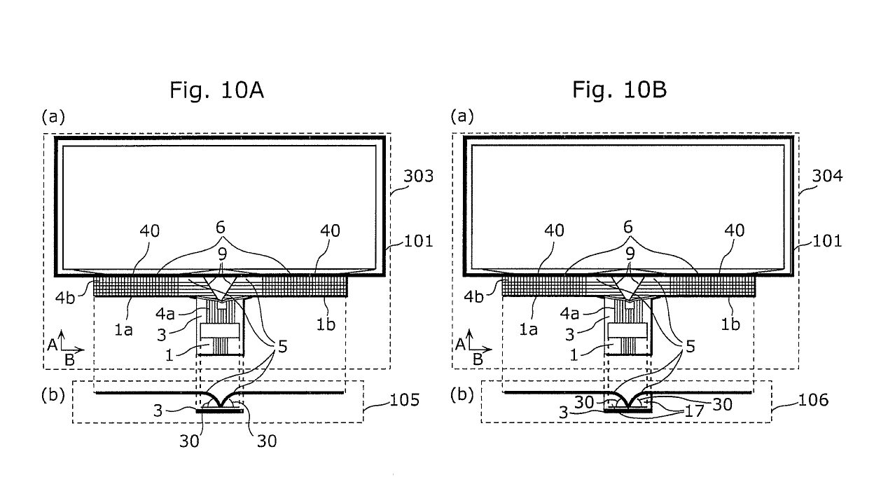

FIG. 9A is a plan view which shows a configuration of a display panel module 302 according to this embodiment. FIG. 9B is a plan view which shows a shape of a driving device 104 before mounted on a liquid crystal panel 101, according to this embodiment.

In FIG. 9A, the display panel module 302 includes: the liquid crystal panel 101; and the driving device 104 which is connected to substrate wires 6 included in the liquid crystal panel 101 and drives the liquid crystal panel 101. The driving device 104 is mounted on an outer edge of the liquid crystal panel 101 and includes a film 1 on which wires 4 and a circuit element 2 are mounted. It is to be noted that the display panel module 302 according to this embodiment is included in a display apparatus in the same manner as in FIG. 4A to FIG. 4C.

As shown in FIG. 9B, the driving device 104 uses the film 1 as a base material. The circuit element 2 is mounted on the film 1, and the wires 4 are provided on the film 1, for guiding signals inputted to and outputted from the circuit element 2.

The film 1 is provided with a linear slit 9 having no bend and bent slits 10 (a second slit). A crack prevention part 11 is provided at each end of the slits 9 and 10 so that a crack is prevented from occurring in the film 1 due to vibration or horizontal oscillation. The driving device 104 includes a first film portion 1a and a second film portion 1b which are obtained by separating the film 1 at the slit 9. Each of the first film portion 1a and the second film portion 1b is folded at least once to be connected to the liquid crystal panel 101. Each of the bent slits 10 is provided to a corresponding one of the first film portion 1a and the second film portion 1b. Each of the first film portion 1a and the second film portion 1b is folded, for example, an even number of times to be connected to the liquid crystal panel 101.

The wires 4 are connected to the circuit element 2 and include: first wires 4a; and second wires 4b connected to the first wires 4a. In the state before the film 1 is folded, the first wires 4a extend in a first direction A, and the second wires 4b extend in a second direction B. The slit 9 extends in the first direction A in the state before the film 1 is folded. The film 1 has a length longer in the first direction A than a length in the second direction B in the state before the film 1 is folded. In this case, since the film 1 has a rectangular planar shape in the state before the film 1 is folded, the first direction A is the direction of the long side of the film 1 and the second direction B is the direction of the short side of the film 1, and thus the slit 9 is formed in the short side of the film 1. Terminals 40 connected to the second wires 4b and to be connected to the substrate wires 6 are aligned on the long sides of the film 1 in the direction of the long side in the state before the film 1 is folded.

In manufacturing the driving device 104, part of the film 1 is separated into the first film portion 1a and the second film portion 1b by providing the film 1 with the slit 9. Each of the first film portion 1a and the second film portion 1b is folded at least twice and connected to the liquid crystal panel 101, thereby being mounted on the liquid crystal panel 101.

Each of the crack prevention part 11 may be a circular hole 25 for preventing a crack, as shown in FIG. 2A, an eyelet 26 provided on the film 1 for preventing a crack, as shown in FIG. 2B, or simply, a tape material bonded to the film 1, for example.

It is to be noted that the crack prevention part 11 may be omitted when a film material which is resistant to cracking is used or it can be determined that an implementation problem involving a crack is unlikely to occur even when the crack prevention part 11 is not added.

FIG. 9C is a diagram which shows a shape of the driving device 104 shown in FIG. 9B mounted on the liquid crystal panel 101.

When mounting the driving device 104 onto the liquid crystal panel 101, the two portions separated at the slit 9 of the film 1 are respectively folded at the folding positions 8, and then respectively folded further using the slits 10 at the folding positions 16.

In addition, given that the film 1 has a front surface where the circuit element 2 is mounted and a rear surface on the other side, the wires 4 on the film portion 5 face the side of the front surface by folding an even number of times (twice, in this case) the right and left portions of the film 1 separated at the slit 9.

The wires 4 facing the side of the front surface and the substrate wires 6 on the liquid crystal panel 101 are connected, thereby configuring the display panel module 302 shown in FIG. 6A.

The distance d4 of the right portion and the left portion separated at the slit 9 of the film 1 of the driving device 104 mounted on the liquid crystal panel 101 is longer than the distance d2 and the distance d3. The distance d2 is a distance of the right portion and the left portion separated at the slit 9 of the film 1 of the driving device 102 mounted on the liquid crystal panel 101 shown in FIG. 3B. The distance d3 is a distance of the right portion and the left portion separated at the slit 9 of the film portion 5 of the driving device 103 mounted on the liquid crystal panel 101 shown in FIG. 7C.

As a result, the driving device 104 can be connected to the liquid crystal panel 101 without increasing the size of the film 1 even when the liquid crystal panel 101 is large in size. Thus, it is possible to obtain the advantageous effect of further lowering costs compared to the conventional techniques with which the size of a film needs to be increased according to the size of the liquid crystal panel.

In addition, the wires are provided so that each of the folding positions 16 becomes vertical with respect to the wires 4 on the film 1, thereby producing the advantageous effect that the same portion is not folded twice in the area d5 shown in FIG. 9C.

### Embodiment 4

FIG. 10A is a diagram which shows a configuration of a display panel module 303 according to this embodiment. It is to be noted that, in FIG. 10A, (a) shows a plan view of the display panel module 303 and (b) shows a side view of a driving device 105. It is to be noted that the display panel module 303 according to this embodiment is included in a display apparatus in the same manner as in FIG. 4A to FIG. 4C.

The display panel module 303 includes: a liquid crystal panel 101; and a driving device 105 which is connected to a substrate wires 6 included in the liquid crystal panel 101 and drives the liquid crystal panel 101. The driving device 105 is mounted on an outer edge of the liquid crystal panel 101 and includes a film 1 on which wires 4 and a circuit element 2 are mounted. The driving device 105 includes a first film portion 1a and a second film portion 1b which are obtained by separating the film 1 at the slit 9. Each of the first film portion 1a and the second film portion 1b is folded at least once to be connected to the liquid crystal panel 101. Each of the first film portion 1a and the second film portion 1b is folded, for example, an odd number of times to be connected to the liquid crystal panel 101. Each of the first film portion 1a and the second film portion 1b is folded with a constant curvature.

The wires 4 are connected to the circuit element 2 and includes: first wires 4a; and second wires 4b connected to the first wires 4a. In the state before the film 1 is folded, the first wires 4a extend in a first direction A, and the second wires 4b extend in a second direction B. The slit 9 extends in the first direction A in the state before the film 1 is folded. The film 1 has a length longer in the first direction A than a length in the second direction B in the state before the film 1 is folded. In this case, since the film 1 has a rectangular planar shape in the state before the film 1 is folded, the first direction A is the direction of the long side of the film 1 and the second direction B is the direction of the short side of the film 1, and thus the slit 9 is formed in the short side of the film 1. Terminals 40 connected to the second wires 4b and to be connected to the substrate wires 6 are aligned on the long sides of the film 1 in the direction of the long side in the state before the film 1 is folded.

In manufacturing the driving device 105, part of the film 1 is separated into the first film portion 1a and the second film portion 1b by providing the film 1 with the slit 9. Each of the first film portion 1a and the second film portion 1b is folded at least once and connected to the liquid crystal panel 101, thereby being mounted on the liquid crystal panel 101.

In the driving device 105 described above, the film portion 3 and the film portion 5 are bonded at an overlapping portion using an adhesive material 18 to fix the shape of the driving device 102. Whereas, in the driving device 105 according to the present embodiment, the driving device 105 is mounted onto the liquid crystal panel 101 such that the film portion 3 and the film portion 5 maintain the constant curvature 30 at the overlapping portion and the adhesive material 18 is not used for bonding.

With this configuration, since the curvature 30 of a bend between the film portion 3 and the film portion 5 which has been maintained to be constant can change when vibration or horizontal oscillation is applied to the liquid crystal panel 101, it is possible to obtain the advantageous effect of absorbing vibration or shock and reducing the rate of disconnection of the wires 4 that exist at the folding positions 8 of the driving device 105 and wire disconnection between the substrate wires 6 of the liquid crystal panel 101 and the driving device 105.

### Embodiment 5

FIG. 10B is a diagram which shows a configuration of a display panel module 304 according to this embodiment. It is to be noted that, in FIG. 10B, (a) shows a plan view of the display panel module 304 and (b) shows a side view of a driving device 106. It is further to be noted that the display panel module 304 according to this embodiment is included in a display apparatus in the same manner as in FIG. 4A to FIG. 4C.

The display panel module 304 includes: a liquid crystal panel 101; and a driving device 106 which is connected to a substrate wires 6 included in the liquid crystal panel 101 and drives the liquid crystal panel 101. The driving device 106 is mounted on an outer edge of the liquid crystal panel 101 and includes a film 1 on which wires 4 and a circuit element 2 are mounted. The driving device 106 includes a first film portion 1a and a second film portion 1b which are obtained by separating the film 1 at the slit 9. Each of the first film portion 1a and the second film portion 1b is folded at least once to be connected to the liquid crystal panel 101. Each of the first film portion 1a and the second film portion 1b is folded, for example, an odd number of times to be connected to the liquid crystal panel 101. Each of the first film portion 1a and the second film portion 1b is folded with a constant curvature.

The wires 4 are connected to the circuit element 2 and include: first wires 4a; and second wires 4b connected to the first wires 4a. In the state before the film 1 is folded, the first wires 4a extend in a first direction A, and the second wires 4b extend in a second direction B. The slit 9 extends in the first direction A in the state before the film 1 is folded. The film 1 has a length longer in the first direction A than a length in the second direction B in the state before the film 1 is folded. In this case, since the film 1 has a rectangular planar shape in the state before the film 1 is folded, the first direction A is the direction of the long side of the film 1 and the second direction B is the direction of the short side of the film 1, and thus the slit 9 is formed in the short side of the film 1. Terminals 40 connected to the second wires 4b and to be connected to the substrate wires 6 are aligned on the long sides of the film 1 in the direction of the long side in the state before the film 1 is folded.

In manufacturing the driving device 106, part of the film 1 is separated into the first film portion 1a and the second film portion 1b by providing the film 1 with the slit 9. Each of the first film portion 1a and the second film portion 1b is folded at least once and connected to the liquid crystal panel 101, thereby being mounted on the liquid crystal panel 101.

The driving device 106 includes a curvature fixing unit 17 for fixing (maintaining) a constant curvature of the bend between the first film portion 1a and the second film portion 1b, in addition to the configuration of the driving device 105.

The curvature fixing unit 17 is inserted between the film portion 3 and the film portion 5 at an overlapping portion thereof and bonded to at least one of the film portion 3 and the film portion 5, thereby fixing the shape of the driving device 105; that is, the curvature 30 of the bend between the film portion 3 and the film portion 5. For the curvature fixing unit 17, a molded plastic is used, for example. In addition, it is not necessarily have to be a solid material, and the same advantageous effect can be obtained with a soft material such as sponge.

With this configuration, the curvature 30 of the bend between the film portion 3 and the film portion 5 which has been maintained to be constant can change when vibration or horizontal oscillation is applied to the liquid crystal panel 101. In addition, even after the curvature 30 changes, the curvature 30 can return to the constant curvature 30 before the change. Therefore, since the curvature 30 of the bend between the film portion 3 and the film portion 5 can return to be constant even after continuous or intermittent vibration or shock is applied, it is possible to obtain the advantageous effect that the shape having the constant curvature 30 of the bend between the film portion 3 and the film portion 5 can be easily maintained, and thus aging degradation or the like is less likely to happen.

### Embodiment 6

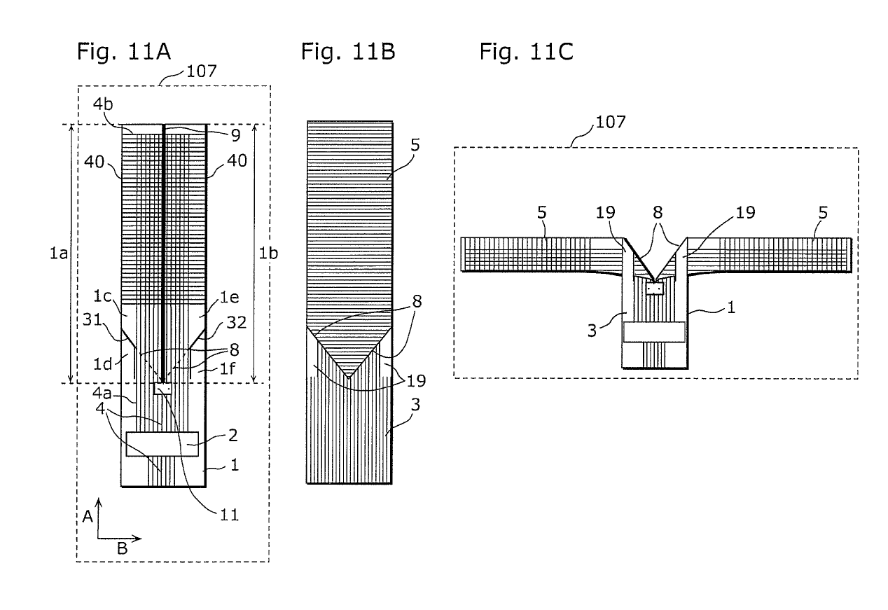

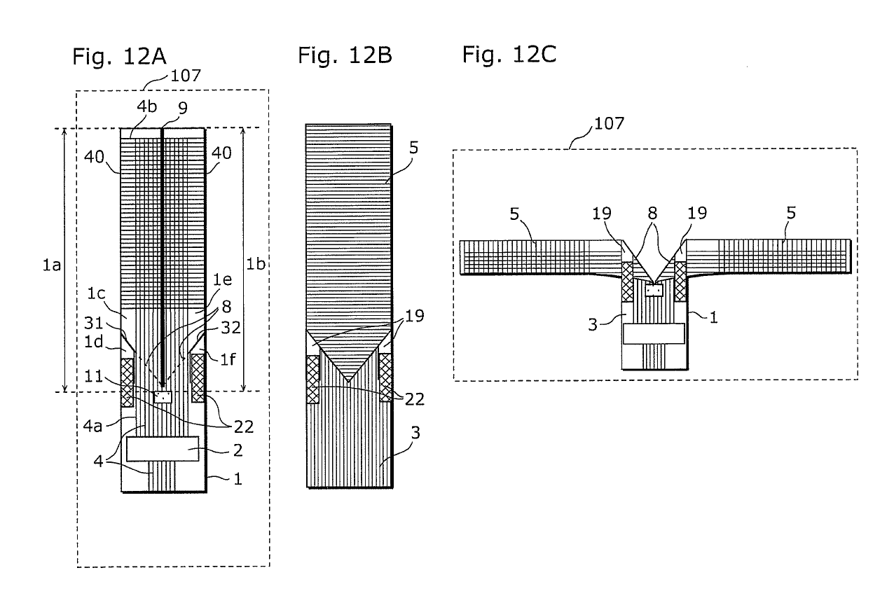

FIG. 11A and FIG. 11B are plan views which show shapes of a driving device 107 before mounted on a liquid crystal panel 101, according to this embodiment.

The driving device 107 is mounted on an outer edge of the liquid crystal panel 101, includes a film 1 on which wires 4 and a circuit element 2 are mounted, and drives the liquid crystal panel 101. It is to be noted that the driving device 107 according to the present embodiment is also included in a display panel module 300 in the same manner as in FIG. 1A and included in a display apparatus in the same manner as in FIG. 4A to FIG. 4C.

As shown in FIG. 11A, the driving device 107 uses the film 1 as a base material. The circuit element 2 is mounted on the film 1, and the wires 4 are provided on the film 1, for guiding signals inputted to and outputted from the circuit element 2. The film 1 is provided with a linear slit 9 having no bend. A crack prevention part 11 is provided at the end of the slit so that a crack is prevented from occurring in the film 1 due to vibration or horizontal oscillation. It is to be noted that the crack prevention part 11 can be omitted when a film material free from a crack is used as the film 1. The driving device 107 includes a first film portion 1a and a second film portion 1b which are obtained by separating the film 1 at the slit 9. Each of the first film portion 1a and the second film portion 1b is folded at least once to be connected to the liquid crystal panel 101. Each of the first film portion 1a and the second film portion 1b is folded, for example, an odd number of times to be connected to the liquid crystal panel 101.

The wires 4 are connected to the circuit element 2 and includes: first wires 4a; and second wires 4b connected to the first wires 4a. In the state before the film 1 is folded, the first wires 4a extend in a first direction A, and the second wires 4b extend in a second direction B. The slit 9 extends in the first direction A in the state before the film 1 is folded. The film 1 has a length longer in the first direction A than a length in the second direction B in the state before the film 1 is folded. In this case, since the film 1 has a rectangular planar shape in the state before the film 1 is folded, the first direction A is the direction of the long side of the film 1 and the second direction B is the direction of the short side of the film 1, and thus the slit 9 is formed in the short side of the film 1. Terminals 40 connected to the second wires 4b and to be connected to the substrate wires 6 are aligned on the long sides of the film 1 in the direction of the long side in the state before the film 1 is folded.

In addition, as shown in FIG. 11A and FIG. 11B, the film portion 3 includes a film fixing portions 19 for fixing the film portion 5 when the film 1 is folded into the shape to be mounted to the liquid crystal panel 101. The film fixing portions 19 are formed by providing the film portion 3 with a slit 31 and a slit 32.

In other words, the first film portion 1a includes a third film portion 1c and a fourth film portion 1d which are separated by providing the first film portion 1a with the slit 31 (third slit). Likewise, the second film portion 1b includes a fifth film portion 1e and a sixth film portion if which are separated by providing the second film portion 1b with the slit 32 (fourth slit). The third film portion 1c is folded at a corresponding one of the folding positions 8 and inserted into the slit 31. The fifth film portion 1e is folded at a corresponding one of the folding positions 8 and inserted into the slit 32.

The film 1 is folded at the folding positions 8, and an angle 27 between a folding line of each of the folding positions 8 and the slit 9 is, for example, 45 degrees.

In manufacturing the driving device 107 shown in FIG. 11C, part of the film 1 is separated into the first film portion 1a and the second film portion 1b by providing the film 1 with the slit 9. In addition, the first film portion 1a is separated into the third film portion 1c and the fourth film portion 1d by providing the first film portion 1a with the slit 31, and the third film portion is folded and inserted into the slit 31; that is, a downward part of the fourth film portion 1d. Furthermore, the second film portion 1b is separated into the fifth film portion 1e and the sixth film portion 1f by providing the first film portion 1a with the slit 32, and the fifth film portion 1e is folded and inserted into the slit 32; that is, a downward part of the sixth film portion 1f. Finally, each of the third film portion 1c and the fifth film portion 1e is connected to the liquid crystal panel 101, thereby being mounted onto the liquid crystal panel 101.

FIG. 11C is a plan view which shows a shape of the driving device 107 shown in FIG. 11A mounted on the liquid crystal panel 101.

When mounting the driving device 107 onto the liquid crystal panel 101, the two portions separated at the slit 9 of the film 1 are respectively folded at the folding positions 8. At this time, in order to prevent the folded film 1 from changing its shape, due to resilience, from the shape shown in the driving device 107 of FIG. 11C to the shape before mounted, the film portion 5 is sandwiched between each of the film fixing portions 19 and the film portion 3, thereby fixing the shape of the driving device 107.

It is to be noted that, when the resilience of the film portion 5 cannot be suppressed with the configuration shown in FIG. 11A to FIG. 11C, a bend preventing material 22 that suppresses a bend of the film fixing portions 19 may be provided to each of the film fixing portions 19 to suppress the resilience of the film fixing portion 19, as shown in FIG. 12A, FIG. 12B, and FIG. 12C. In other words, the resilience of the film fixing portion 19 is suppressed by providing the fourth film portion 1d and the sixth film portion 1f with the bend preventing material 22 made from a bend preventing material that is further resistant to bending than the fourth film portion 1d and the sixth film portion 1f. The film fixing portion 19 is a member such as a metal plate or the like, which is further resistant to deformation than the film 1.

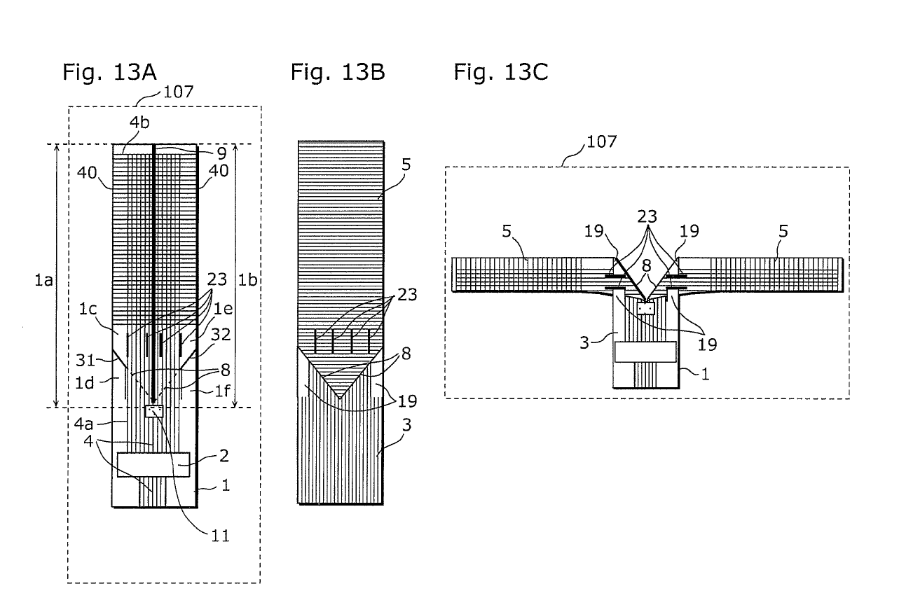

It is to be noted that, the shape of the driving device 107 may be fixed by newly providing the film portion 5 with cuts 23 for fixing the film portion 5 as cuts into which the film fixing portions 19 are inserted as shown in FIG. 13A and FIG. 13B, and inserting the film fixing portions 19 into the cuts 23 for fixing the film portion 5. More specifically, the third film portion 1c may be provided with at least one of the cuts 23 into which the fourth film portion 1d is inserted, and the fifth film portion 1e may be provided with at least one of the cuts 23 into which the sixth film portion 1f is inserted. At this time, each of the third film portion 1c and the fifth film portion 1e may be provided with only one of the cuts 23, or may be provided with more than one of the cuts 23.

In manufacturing the driving device 107 shown in FIG. 13C, part of the film 1 is separated into the first film portion 1a and the second film portion 1b by providing the film 1 with the slit 9. In addition, the first film portion 1a is separated into the third film portion 1c and the fourth film portion 1d by providing the first film portion 1a with the slit 31, and the third film portion 1c is folded and inserted into the slit 31; that is, a downward part of the fourth film portion 1d. Furthermore, the second film portion 1b is separated into the fifth film portion 1e and the sixth film portion 1f by providing the first film portion 1a with the slit 32, and the fifth film portion 1e is folded and inserted into the slit 32; that is, a downward part of the sixth film portion 1f. Finally, the fourth film portion 1d is inserted into the cut 23 of the third film portion 1c and the sixth film portion 1f is inserted into the cut 23 of the fifth film portion 1e, and then the third film portion 1c and the fifth film portion 1e are connected to the liquid crystal panel 101, thereby being mounted onto the liquid crystal panel 101.

Since the shape of the driving device 107 is fixed with the above-described configuration, the shape of the wires 4 at the folding positions 8 is less likely to change when vibration or horizontal oscillation is applied to the liquid crystal panel 101, and thus it is possible to obtain the advantageous effect of lowering the probability of occurrence of wire disconnection of the wires 4.

It should be appreciated that the detailed embodiments in the Description of Embodiments of the present invention are provided merely for clarifying the techniques of the present invention, and the present invention should not to be limited only to such a detailed example or construed narrowly, but can be implemented with various modifications within the scope of the spirit of this invention. In addition, elements of different embodiments may arbitrarily be combined within the scope of the present invention.

For example, the driving device is provided on one side of the liquid crystal panel in the above-described embodiments; however, the driving device may be provided on two or more sides when the display panel module is used for a display apparatus which requires a high-speed operation such as a 3D display apparatus.

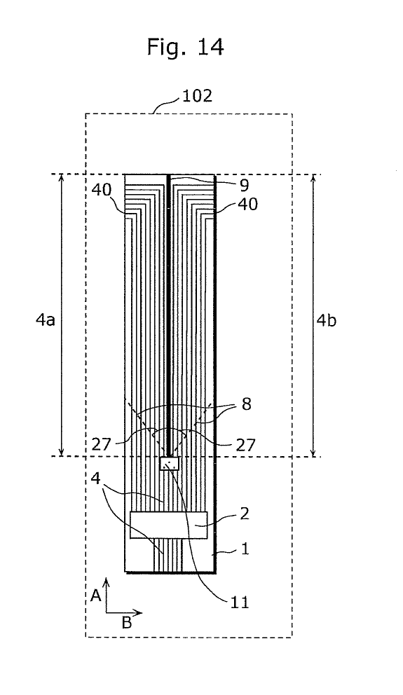

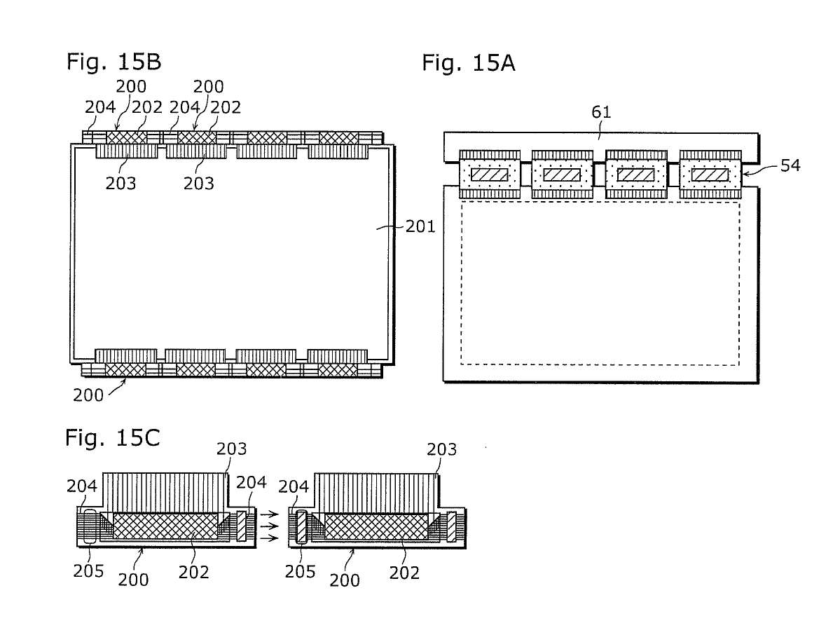

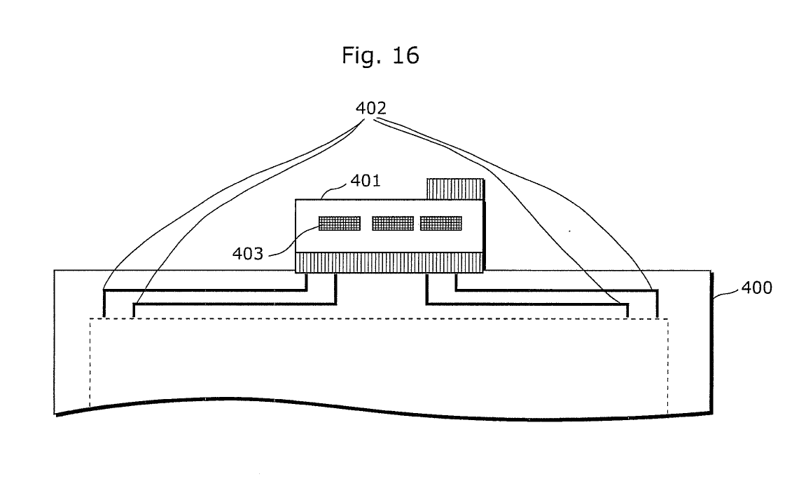

In addition, wires of the driving device are provided in two layers on one surface of the film, in the above-described embodiments. However, as shown in FIG. 14, wires of the driving device may be provided in a single layer on one surface of the film and arranged in L-shape to bend in the second direction at the end of the first direction.

### INDUSTRIAL APPLICABILITY

The present invention is useful for a driving device, a display panel module, a display apparatus, and a method of manufacturing the driving device, and particularly useful for a display apparatus such as a liquid crystal television, a liquid crystal monitor, an organic electroluminescence television, an organic electroluminescence monitor, and so on.

### REFERENCE SIGNS LIST

1 film
1a first film portion
1b second film portion
1c third film portion
1d fourth film portion
1e fifth film portion
1f sixth film portion
2 circuit element
3, 5 film portion
4, 402 wires
4a first wires
4b second wires
6 substrate wires
8, 16, 24 folding position
9, 10, 31, 32 slit
11 crack prevention part
12 heat dissipation unit
14 heat-conducting material
15 fixing frame
17 curvature fixing unit
18 adhesive material
19 film fixing portion
20 wire strengthening portion
21 wiring prohibited portion
22 bend preventing material
23 cut
25 hole
26 eyelet
27 angle
30 curvature
40 terminal
54, 200, 401 semiconductor device
61 wiring board
101, 400 liquid crystal panel
102, 103, 104, 105, 106, 107 driving device
201 liquid crystal panel
202 semiconductor chip
203, 204 outer lead
205 slit
300, 301, 302, 303, 304 display panel module
403 semiconductor element
d1, d5 area
d2, d3, d4 distance

1-28. (canceled)

29. A driving device for driving a display panel, said driving device comprising:
wires;
a circuit element;
a film on which said wires and said circuit element are mounted; and
a first film portion and a second film portion separated by providing a first slit in said film,
wherein each of said first film portion and said second film portion is folded at least once and connected to the display panel.

30. The driving device according to claim 29,
wherein the first slit is linear.

31. The driving device according to claim 30,
wherein each of said first film portion and said second film portion is further provided with a second slit having a bend.

32. The driving device according to claim 29,
further comprising a crack prevention part at an end of at least one of the first slit and the second slit in said film.

33. The driving device according to claim 29,
wherein each of said first film portion and said second film portion is folded an even number of times and connected to the display panel.

34. The driving device according to claim 29,
wherein each of said first film portion and said second film portion is folded an odd number of times and connected to the display panel.

35. The driving device according to claim 33,
wherein a width of each of said wires is enlarged at a folding position of said film.

36. The driving device according to claim 33,
wherein said wires are not provided at folding positions where said film is folded more than once.

37. The driving device according to claim 33,
wherein each of said first film portion and said second film portion is folded along a line which serves as a folding position, the line being at a 45 degrees angle with respect to the first slit.

38. The driving device according to claim 33,
wherein each of said first film portion and said second film portion is folded along a line which serves as a folding position, the line being at a less than 45 degrees angle with respect to the first slit.

39. The driving device according to claim 37,
wherein each of said first film portion and said second film portion is folded with a constant curvature.

40. The driving device according to claim 39,
further comprising a curvature fixing unit configured to maintain the constant curvature.

41. The driving device according to claim 37,
wherein a folded portion and a non-folded portion in said film are bonded to each other using an adhesive material.

42. The driving device according to claim 37,
wherein said first film portion includes a third film portion and a fourth film portion separated by providing a third slit in said first film portion,
said second film portion includes a fifth film portion and a sixth film portion separated by providing a fourth slit in said second film portion,
said third film portion is folded and inserted into the third slit, and
said fifth film portion is folded and inserted into the fourth slit.

43. The driving device according to claim 42,
further comprising a bend preventing material in said fourth film portion and said sixth film portion, said bend preventing material being more resistant to bending than said fourth film portion and said sixth film portion.

44. The driving device according to claim 42,
wherein said third film portion is provided with a cut into which said fourth film portion is inserted, and
said fifth film portion is provided with a cut into which said sixth film portion is inserted.

45. The driving device according to claim 29,
wherein said wires include first wires connected to said circuit element, said first wires extending in a first direction in a state before said film is folded, and
the first slit extends in the first direction in the state before said film is folded.

46. The driving device according to claim 45,
wherein said wires include second wires connected to said first wires, said second wires extending in a second direction in the state before said film is folded, and
said film is longer in the first direction than in the second direction in the state before said film is folded.

47. The driving device according to claim 46,
wherein said film has a rectangular planar shape in the state before said film is folded,
the first direction is a direction of a long side of said film,
the second direction is a direction of a short side of said film, and
the first slit is provided in the short side of said film.

48. The driving device according to claim 47,
wherein said film includes, in the long side, terminals connected to said second wires and aligned in the direction of the long side in the state before said film is folded.

49. The driving device according to claim 45,
wherein said film has a planar shape and a width that decreases toward an edge of the first direction in the state before said film is folded, and
the first slit is provided in the edge of the first direction of said film.

50. The driving device according to claim 49,
wherein said first wires extend to the edge of said film, and
said film includes, at the edge of the first direction, terminals connected to said first wires.

51. A display panel module comprising:
a display panel; and
said driving device according to claim 29, mounted on an outer edge of said display panel.

52. A display apparatus comprising:
a display panel;
said driving device according to claim 29; and
a fixing frame for fixing a position of said display panel and said driving device, said display panel and said driving device being provided inside said fixing frame.

53. The display apparatus according to claim 52,
wherein said circuit element is directly in contact with said fixing frame.

54. The display apparatus according to claim 53,
wherein said fixing frame includes a projection which projects inwardly, and
said circuit element is directly in contact with said projection.

55. The display apparatus according to claim 52,
wherein said circuit element is in contact with said fixing frame via a material having high thermal conductivity.

56. A method of manufacturing a driving device which drives a display panel and includes wires, a circuit element, and a film on which the wires and the circuit element are mounted, said method comprising
providing a first slit in the film to separate part of the film into a first film portion and a second film portion, and
folding each of the first film portion and the second film portion at least once to connect the first film portion and the second film portion to the display panel.
